(19) United States
(12) Patent Application Publication
(10) Pub. No.: US 2014/0070161 A1
(43) Pub. Date: Mar. 13, 2014

(54) MEMORY DEVICE

(71) Applicant: KABUSHIKI KAISHA TOSHIBA, Tokyo (JP)

(72) Inventors: Kikuko SUGIMAE, Kanagawa-ken (JP); Kiyohito Nishihara, Kanagawa-ken (JP); Junya Matsunami, Kanagawa-ken (JP)

(73) Assignee: Kabushiki Kaisha Toshiba, Tokyo (JP)

(21) Appl. No.: 13/775,397

(22) Filed: Feb. 25, 2013

(30) Foreign Application Priority Data
Sep. 10, 2012 (JP) 2012-198176

(51) Int. Cl. H01L 45/00

(52) U.S. Cl. CPC H01L 45/12
USPC 257/4

(57) ABSTRACT

According to one embodiment, a memory device includes a first interconnect, a second interconnect and a pillar connected between the first interconnect and the second interconnect. The pillar includes a first high-resistance layer, a second high-resistance layer, and a metal layer. The first high-resistance layer is connected to the first interconnect. A resistivity of the first high-resistance layer is higher than a resistivity of the first interconnect and a resistivity of the second interconnect. The second high-resistance layer is connected to the second interconnect. A resistivity of the second high-resistance layer is higher than the resistivity of the first high-resistance layer. A thickness of the second high-resistance layer is not more than a thickness of the first high-resistance layer. The metal layer is disposed between the first high-resistance layer and the second high-resistance layer. The metal layer includes a metal.

### CROSS-REFERENCE TO RELATED APPLICATIONS

This application is based upon and claims the benefit of priority from the prior Japanese Patent Application No. 2012-198176, filed on Sep. 10, 2012; the entire contents of which are incorporated herein by reference.

### FIELD

Embodiments described herein relate generally to a memory device.

### BACKGROUND

Ionic memory has been proposed as a next-generation flash memory. In ionic memory, a low resistance state is realized by forming a metal filament in an insulating film by causing metal ions to diffuse into the insulating film and precipitate as a simple substance. A high resistance state is realized by breaking the current path by causing at least a portion of the metal filament to vanish. Binary data is stored by switching between the low resistance state and the high resistance state.

### BRIEF DESCRIPTION OF THE DRAWINGS

FIG. 1 is a perspective view showing a memory device according to a first embodiment;

FIG. 2 is a cross-sectional view showing a pillar of the memory device according to the first embodiment;

FIGS. 3A to 3D are schematic cross-sectional views showing the operations of the memory device according to the first embodiment;

FIG. 4 is a cross-sectional view showing the pillar of a memory device according to a second embodiment;

FIGS. 5A to 5C are cross-sectional views of processes showing the method for manufacturing the memory device according to the second embodiment; and

FIG. 6 is a cross-sectional view showing the pillar of a memory device according to a third embodiment.

### DETAILED DESCRIPTION

In general, according to one embodiment, a memory device includes a first interconnect extending in a first direction, a second interconnect extending in a second direction crossing the first direction, and a pillar connected between the first interconnect and the second interconnect. The pillar includes a first high-resistance layer, a second high-resistance layer, and a metal layer. The first high-resistance layer is connected to the first interconnect. A resistivity of the first high-resistance layer is higher than a resistivity of the first interconnect and a resistivity of the second interconnect. The second high-resistance layer is connected to the second interconnect. A resistivity of the second high-resistance layer is higher than the resistivity of the first high-resistance layer. A thickness of the second high-resistance layer is not more than a thickness of the first high-resistance layer. The metal layer is disposed between the first high-resistance layer and the second high-resistance layer. The metal layer includes a metal.

In general, according to one embodiment, a memory device includes a first interconnect extending in a first direction, a second interconnect extending in a second direction crossing the first direction, and a pillar connected between the first interconnect and the second interconnect. The pillar includes a first high-resistance layer and a second high-resistance layer. The first high-resistance layer is connected to the first interconnect. A resistivity of the first high-resistance layer is higher than a resistivity of the first interconnect and a resistivity of the second interconnect. The second high-resistance layer is connected to the second interconnect. A resistivity of the second high-resistance layer is higher than the resistivity of the first high-resistance layer. A thickness of the second high-resistance layer is not more than a thickness of the first high-resistance layer. The second high-resistance layer includes a metal.

Embodiments of the invention will now be described with reference to the drawings.

First, a first embodiment will be described.

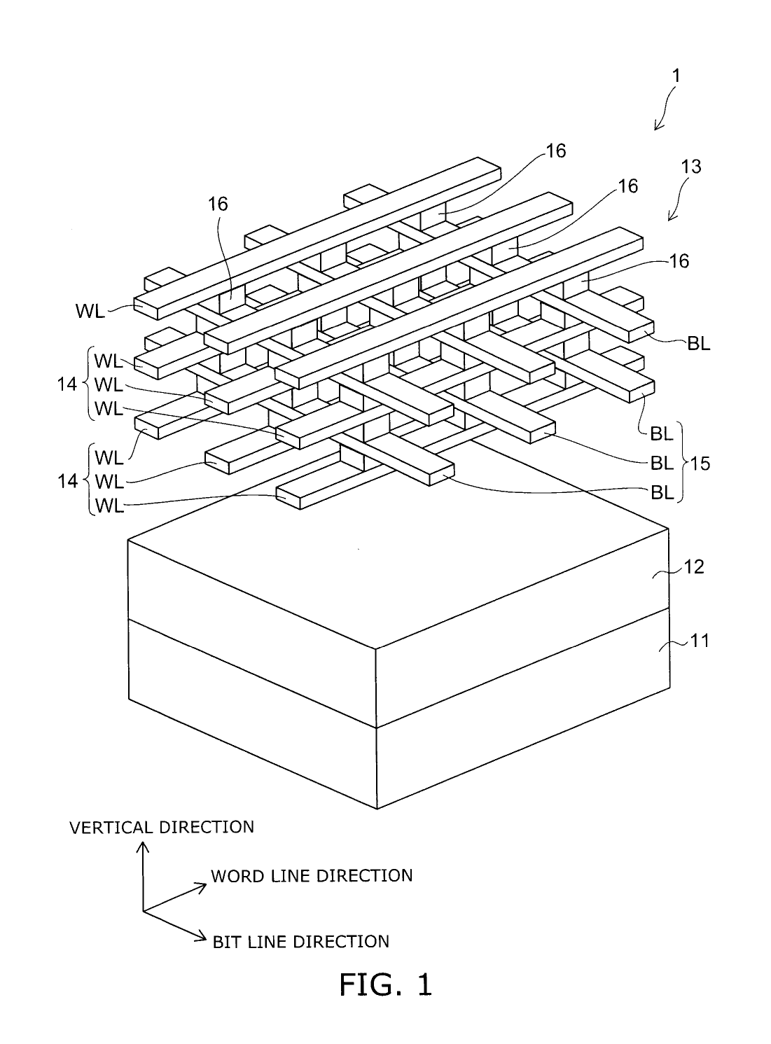

FIG. 1 is a perspective view showing a memory device according to the embodiment.

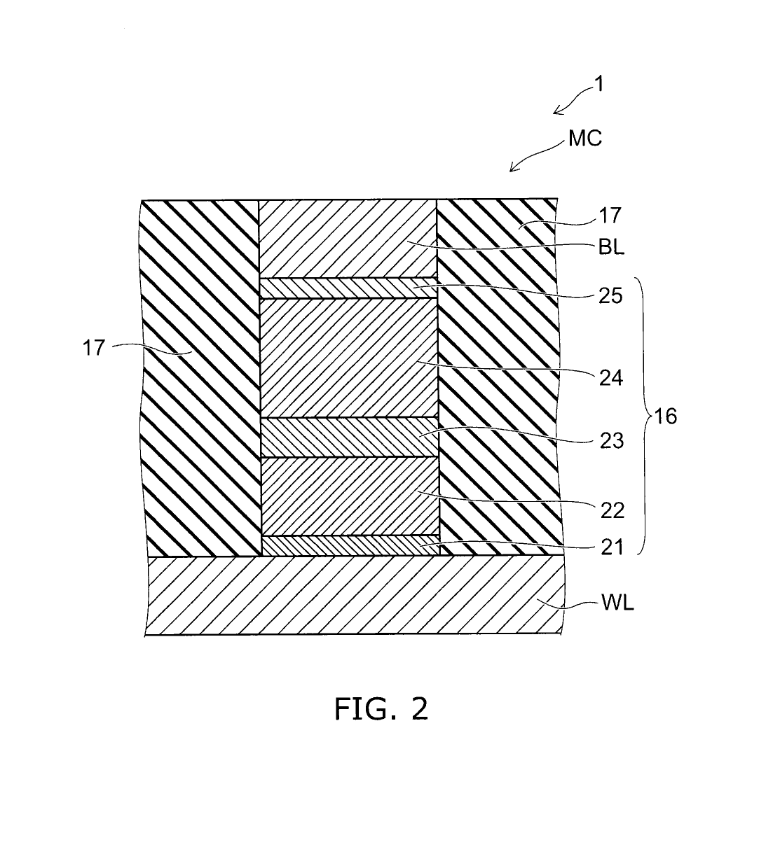

FIG. 2 is a cross-sectional view showing a pillar of the memory device according to the embodiment.

The memory device according to the embodiment is an ionic memory.

In the memory device 1 according to the embodiment as shown in FIG. 1, a silicon substrate 11 is provided; and a drive circuit (not shown) of the memory device 1 is formed at the upper layer portion of the silicon substrate 11 and on the upper surface of the silicon substrate 11. An inter-layer insulating film 12 made of, for example, silicon oxide is provided on the silicon substrate 11 to bury the drive circuit; and a memory cell unit 13 is provided on the inter-layer insulating film 12.

In the memory cell unit 13, a word line interconnect layer 14 including multiple word lines WL extending in one direction (hereinbelow referred to as a “word line direction”) parallel to the upper surface of the silicon substrate 11 is alternately stacked with a bit line interconnect layer 15 including multiple bit lines BL extending in a direction (hereinbelow referred to as a “bit line direction”) parallel to the upper surface of the silicon substrate 11 to cross, e.g., to be orthogonal to, the word line direction. The word lines WL do not contact each other; the bit lines BL do not contact each other; and the word lines WL do not contact the bit lines BL. The word lines WL and the bit lines BL are formed of, for example, tungsten (W).

A pillar 16 is provided at each of the most proximal points between the word lines WL and the bit lines BL to extend in a direction (hereinbelow referred to as a “vertical direction”) perpendicular to the upper surface of the silicon substrate 11. The pillar 16 has, for example, a circular columnar configuration, a quadrilateral columnar configuration, or a substantially quadrilateral columnar configuration having rounded corners. The pillar 16 is formed between the word line WL and the bit line BL; and one memory cell MC includes one pillar 16. In other words, the memory device 1 is a cross-point type device in which the memory cells MC are disposed every most proximal point between the word lines WL and the bit lines BL. An inter-layer insulating film 17 (referring to FIG. 2) is filled around the word lines WL, the bit lines BL, and the pillars 16.

Each of the pillars 16 will now be described.

In the pillar 16 as shown in FIG. 2, a barrier metal layer 21, a silicon oxide layer 22, a silver layer 23, an amorphous silicon layer 24, and a barrier metal layer 25 are stacked in this order from the word line WL side toward the bit line BL side. The barrier metal layers 21 and 25 are layers that suppress diffusion of the materials of the word line WL and the bit line BL into the pillar 16 and are formed of, for example, tungsten nitride (WN) or tantalum nitride (TaN).

The amorphous silicon layer 24 is formed of amorphous silicon and is connected to the bit line BL via the barrier metal layer 25. The resistivity of the amorphous silicon layer 24 is higher than the resistivity of the word line WL, the resistivity of the bit line BL, the resistivity of the barrier metal layer 21, and the resistivity of the barrier metal layer 25. The amorphous silicon layer 24 is thicker than the barrier metal layer 21 and thicker than the barrier metal layer 25.

The silicon oxide layer 22 is formed of silicon oxide and is connected to the word line WL via the barrier metal layer 21. The resistivity of the silicon oxide layer 22 is higher than the resistivity of the amorphous silicon layer 24. The thickness of the silicon oxide layer 22 is not more than the thickness of the amorphous silicon layer 24. The silicon oxide layer 22 is thicker than the barrier metal layer 21 and thicker than the barrier metal layer 25.

The silver layer 23 is made of silver (Ag) and is disposed between the silicon oxide layer 22 and the amorphous silicon layer 24 to contact the silicon oxide layer 22 and the amorphous silicon layer 24. The silver layer 23 is thinner than the silicon oxide layer 22 and the amorphous silicon layer 24 and thicker than the barrier metal layers 21 and 25.

Operations of the memory device according to the embodiment will now be described.

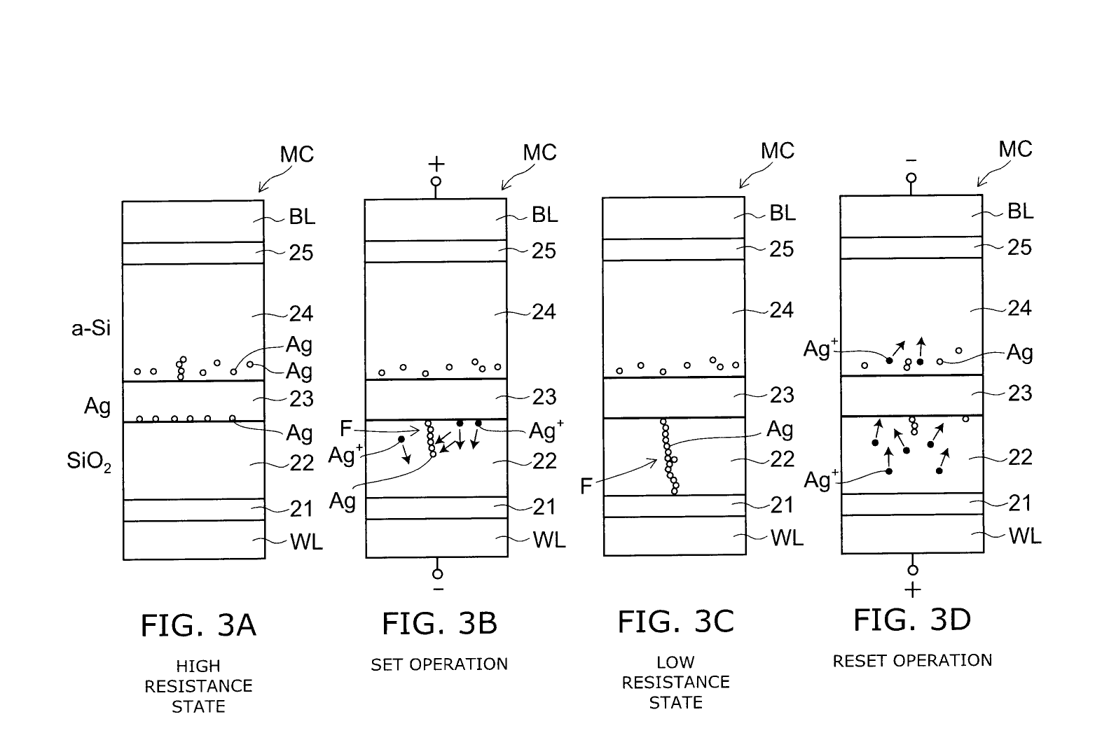

FIGS. 3A to 3D are schematic cross-sectional views showing the operations of the memory device according to the embodiment. FIG. 3A shows the high resistance state; FIG. 3B shows a state partway through the set operation; FIG. 3C shows the low resistance state; and FIG. 3D shows a state partway through the reset operation.

In FIGS. 3A to 3D, simple silver atoms (Ag) are schematically illustrated by white circles (∘); and silver ions (Ag⁺) are schematically illustrated by black circles (•).

As shown in FIG. 3A, when the memory cell MC is in the high resistance state, continuous filaments are not formed inside the silicon oxide layer 22 and inside the amorphous silicon layer 24. Therefore, the silicon oxide layer 22 and the amorphous silicon layer 24 are substantially insulating layers. However, because silver atoms diffuse more easily in the amorphous silicon than in silicon oxide, the number of the silver atoms diffusing from the silver layer 23 into the amorphous silicon layer 24 is greater than the number of the silver atoms diffusing from the silver layer 23 into the silicon oxide layer 22.

As shown in FIG. 3B, when the set operation, i.e., the operation of causing the memory cell MC to transition from the high resistance state to the low resistance state, is performed, a set voltage is applied to the pillar 16 such that the bit line BL becomes a positive electrode and the word line WL becomes a negative electrode. The set voltage applied to the entire pillar 16 is applied to the silicon oxide layer 22 and the amorphous silicon layer 24 by being subdivided according to the ratio of the electrical resistance value of the silicon oxide layer 22 and the electrical resistance value of the amorphous silicon layer 24. At this time, an electric field that is higher than that of the amorphous silicon layer 24 is applied to the silicon oxide layer 22 because the thickness of the silicon oxide layer 22 is not more than the thickness of the amorphous silicon layer 24 and the resistivity of the silicon oxide layer 22 is higher than the resistivity of the amorphous silicon layer 24.

Because the silver atoms substantially are not diffused into the silicon oxide layer 22, the composition change at the interface between the silver layer 23 and the silicon oxide layer 22 is abrupt; and the electric field is applied concentratively at the interface. As a result, the silver atoms (Ag) of the silver layer 23 positioned proximally to the interface between the silver layer 23 and the silicon oxide layer 22 are ionized to become silver ions (Ag⁺) because a strong electric field is applied. The silver ions thus produced respond to the electric field to move through the silicon oxide layer 22 toward the word line WL which is the negative electrode. Then, the silver ions inside the silicon oxide layer 22 return to silver atoms (Ag) by combining with electrons (e⁻) supplied from the word line WL to form a metal filament F.

Then, as shown in FIG. 3C, when the metal filament F formed inside the silicon oxide layer 22 reaches the barrier metal layer 21, the silicon oxide layer 22 is switched to the low resistance state; and the entire memory cell MC is switched to the low resistance state. Thereby, the set operation ends. At this time, the filament F is not formed in the amorphous silicon layer 24; and the amorphous silicon layer 24 functions as a resistor. Thereby, even when the memory cell MC is in the low resistance state, an excessive current does not flow in the memory cell MC because the current flowing in the memory cell MC is limited by the amorphous silicon layer 24.

As shown in FIG. 3D, when the reset operation, i.e., the operation of causing the memory cell MC to transition from the low resistance state to the high resistance state, is performed, a reset voltage is applied to the pillar 16 such that the bit line BL becomes the negative electrode and the word line WL becomes the positive electrode. In the initial stage of the reset operation, the greater part of the reset voltage applied to the entire pillar 16 is applied to the amorphous silicon layer 24 because the filament F is formed inside the silicon oxide layer 22. However, when at least some of the silver atoms forming the filament F is ionized and detaches from the filament F, the reset voltage is subdivided between the silicon oxide layer 22 and the amorphous silicon layer 24 because the silicon oxide layer 22 is switched to the high resistance state. At this time, a relatively strong electric field is applied to the silicon oxide layer 22 which has a relatively high resistivity. Accordingly, a strong electric field is applied to the silver atoms forming the filament F inside the silicon oxide layer 22; and these silver atoms are ionized and move toward the silver layer 23. As a result, at least a portion of the filament F quickly vanishes; and the high resistance state of the silicon oxide layer 22 stabilizes. Thereby, the reset operation ends.

On the other hand, the composition change of the interface between the silver layer 23 and the amorphous silicon layer 24 is not abrupt because many silver atoms are diffused from the silver layer 23 into the amorphous silicon layer 24; and the electric field does not easily concentrate at this interface. Therefore, the silver atoms do not ionize easily. The silver atoms that are not ionized do not move even when the electric field is applied. Moreover, only a weak electric field is applied to the silver ions that are ionized inside the amorphous silicon layer 24 because only a relatively weak electric field is applied to the amorphous silicon layer 24; and these silver ions do not move easily through the amorphous silicon layer 24. Therefore, filaments are not easily formed inside the amorphous silicon layer 24. Further, even if a filament is formed, the filament formed inside the amorphous silicon layer 24 does not reach the barrier metal layer 25 within the time necessary for the filament F inside the silicon oxide layer 22 to vanish because the thickness of the amorphous silicon layer 24 is not less than the thickness of the silicon oxide layer 22.

Thus, although the filament inside the silicon oxide layer 22 vanishes as a result of the reset operation, a filament that reaches the barrier metal layer 25 is not formed inside the amorphous silicon layer 24. Thereby, as shown in FIG. 3A, the memory cell MC as an entirety is switched to the high resistance state.

Effects of the embodiment will now be described.

In the embodiment, the set operation and the reset operation are possible by providing the silicon oxide layer 22 and the amorphous silicon layer 24 on two sides of the silver layer 23 in each of the pillars 16 as described above. In the low resistance state as well, an excessive current does not flow in the memory cell MC because the amorphous silicon layer 24 functions as a resistor. In other words, breakdown of the memory cell MC does not occur due to excessive current because the amorphous silicon layer 24 functions as a compliance layer that limits the amount of current. Accordingly, the memory device 1 according to the embodiment has high reliability.

It also may be considered to limit the current flowing in each of the memory cells MC by providing a current-limiting circuit outside the memory cell unit 13. However, although such an external current-limiting circuit can limit the entire current flowing in the multiple memory cells MC, the current flowing in the individual memory cells MC cannot be limited individually. For example, in the case where each of the word lines WL is connected to the current-limiting circuit, only the total amount of current flowing in the multiple memory cells MC connected to the word line WL can be controlled.

Conversely, according to the embodiment, the amount of current flowing in the individual memory cells MC can be directly limited because the amorphous silicon layer 24 is provided as a current compliance layer in the individual memory cells MC. Thereby, the breakdown of the memory cells MC can be reliably prevented. In the embodiment as well, a current-limiting circuit that limits the amount of current of the entire memory cell unit 13 may be provided separately from the amorphous silicon layer 24.

In the embodiment, even when a voltage that is the reverse of the set voltage, i.e., a voltage in which the word line WL is the positive electrode and the bit line BL is the negative electrode, is applied to the pillar 16 in the high resistance state shown in FIG. 3A, filaments that reach the barrier metal layer 25 are not formed inside the amorphous silicon layer 24 because only a weak electric field is applied to the silver atoms existing inside the amorphous silicon layer 24 and in the silver layer 23 proximally to the interface between the silver layer 23 and the amorphous silicon layer 24. Therefore, misoperations caused by reverse bias can be prevented without providing a diode in the pillar 16. As a result, this is advantageous for higher bit densities because the aspect ratio of the pillar 16 can be lower than that of the case where the diode is provided. Also, the manufacturing processes can be simplified.

A second embodiment will now be described.

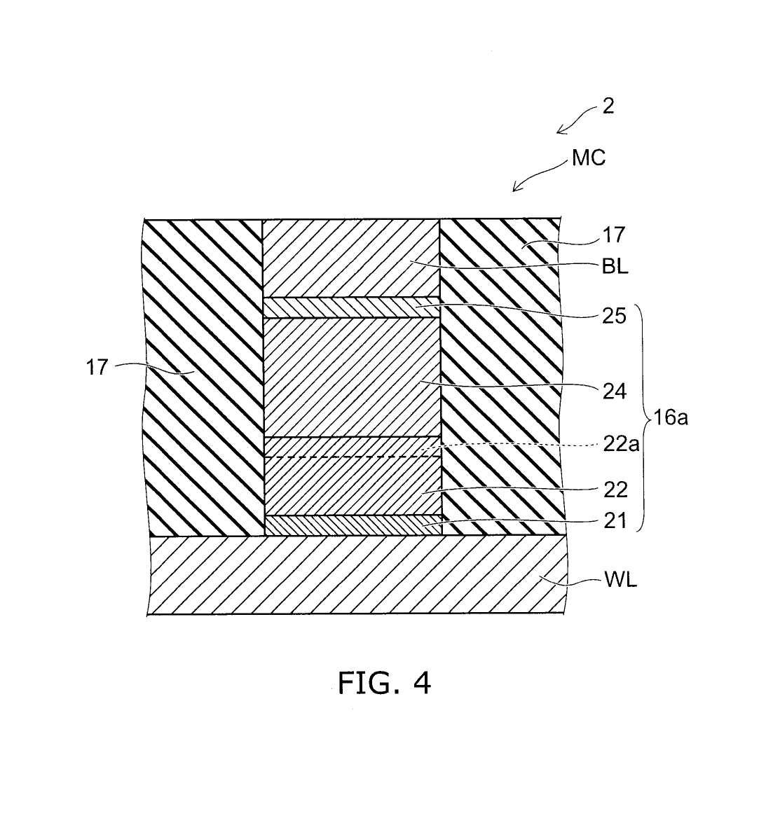

FIG. 4 is a cross-sectional view showing the pillar of a memory device according to the embodiment.

As shown in FIG. 4, a pillar 16a of the memory device 2 according to the embodiment differs from the pillar 16 (referring to FIG. 1) of the memory device 1 according to the first embodiment described above in that the silver layer 23 (referring to FIG. 1) is not provided, and silver is contained inside the silicon oxide layer 22 instead of the silver layer 23. A silver concentration layer 22a is formed in the upper layer portion of the silicon oxide layer 22, i.e., the portion contacting the amorphous silicon layer 24. The silver concentration layer 22a is a portion of the silicon oxide layer 22 where the concentration of silver is higher than that of the other portions of the silicon oxide layer 22. According to the embodiment as well, the silver concentration layer 22a performs a role similar to that of the silver layer 23; and operations similar to those of the first embodiment described above can be executed.

A method for manufacturing the memory device according to the second embodiment will now be described.

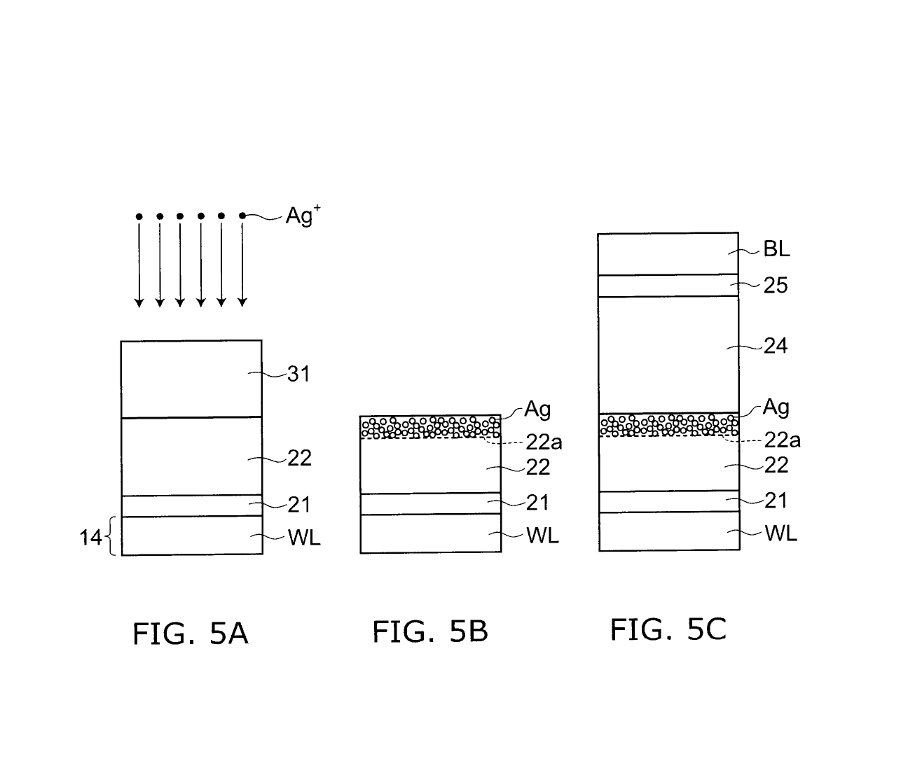

FIGS. 5A to 5C are cross-sectional views of processes showing the method for manufacturing the memory device according to the embodiment.

In FIGS. 5A to 5C, simple silver atoms (Ag) are schematically illustrated by white circles (∘); and silver ions (Ag⁺) are schematically illustrated by black circles (•).

First, as shown in FIG. 5A, the barrier metal layer 21 is formed on the word line interconnect layer 14; and a protective film 31 is formed after forming the silicon oxide layer 22 on the barrier metal layer 21. Then, ion implantation of silver is performed through the protective film 31 into the silicon oxide layer 22.

Thereby, as shown in FIG. 5B, the silver concentration layer 22a is formed at the upper layer portion of the silicon oxide layer 22. At this time, the silicon oxide layer 22 is not easily damaged by the ion implantation because the protective film 31 exists. Subsequently, the protective film 31 is removed. Thereby, the upper surface of the silicon oxide layer 22 is exposed.

Then, as shown in FIG. 5C, the amorphous silicon layer 24 is formed on the silicon oxide layer 22 by depositing amorphous silicon. Continuing, the barrier metal layer 25 is formed on the amorphous silicon layer 24. Then, the pillars 16a are formed by selectively removing the barrier metal layer 25, the amorphous silicon layer 24, the silicon oxide layer 22, and the barrier metal layer 21 by performing dry etching.

Otherwise, the manufacturing method of the embodiment is similar to the method for manufacturing a memory device having a normal cross-point structure.

In the embodiment, the manufacturing of the memory device 2 is easy because the silver which is the ion metal is contained inside the silicon oxide layer 22; and a silver layer does not exist as a metal layer. For example, when forming the pillars 16a by performing dry etching, the patterning can be performed at the conditions for silicon oxide; and it is unnecessary to process the silver layer as the metal layer. The film formation is easy when forming the amorphous silicon layer 24 because the amorphous silicon can be deposited using the silicon oxide layer 22 instead of the metal layer as the foundation. Corrosion of the silver layer does not occur because the silver layer does not exist as the metal layer. On the other hand, because the silver layer 23 is provided in the first embodiment described above, the silver atoms can be ionized more easily at the interface between the silver layer 23 and the silicon oxide layer 22, and the operational stability of the memory cell is higher than for the second embodiment. Otherwise, the configuration, the operations, and the effects of the second embodiment are similar to those of the first embodiment described above.

A third embodiment will now be described.

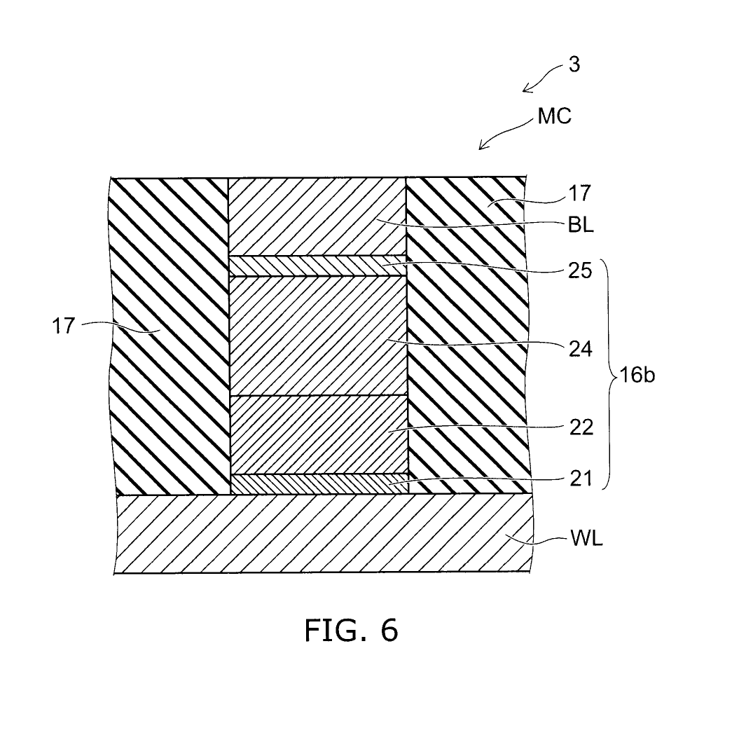

FIG. 6 is a cross-sectional view showing the pillar of a memory device according to the embodiment.

As shown in FIG. 6, the memory device 3 according to the embodiment differs from the memory device 2 (referring to FIG. 4) according to the second embodiment described above in that the silver concentration layer 22a is not provided in the silicon oxide layer 22 of a pillar 16b; and the silver is dispersed in the entire silicon oxide layer 22.

According to the third embodiment, the manufacturing of the memory device is even easier than that of the second embodiment described above because the silver concentration layer 22a does not exist. Conversely, the silver atoms can be ionized more easily and the operational stability of the memory cell is higher for the first and second embodiments described above than for the third embodiment. Otherwise, the configuration, the manufacturing method, the operations, and the effects of the third embodiment are similar to those of the second embodiment described above.

Although an example in which silver is used as the ion metal is illustrated in the embodiments described above, this is not limited thereto. Other than silver, for example, gold (Au), nickel (Ni), or cobalt (Co) may be used as the ion metal.

Although an example is illustrated in the embodiments described above in which silicon oxide and amorphous silicon are used as the materials of the pair of high-resistance layers provided on the two sides of the ion metal layer, this is not limited thereto. Other than amorphous silicon, the materials of the high-resistance layers may be, for example, polysilicon, silicon nitride (SiN), or a material in which a refractory metal is added to silicon nitride. The material in which the refractory metal is added to silicon nitride may include, for example, TaSiN, TiSiN, HfSiN, NbSiN, CrSiN, MoSiN, WSiN, CoSiN, and NiSiN. A high-resistance layer having the desired resistivity can be obtained using these materials.

In the first embodiment described above, buffer layers may be provided between the silicon oxide layer 22 and the silver layer 23 and between the silver layer 23 and the amorphous silicon layer 24. The materials of the buffer layers may include, for example, hafnium oxide (HfO₂), aluminum oxide (Al₂O₃), silicon (Si), polysilicon (polySi), etc. However, the composition ratios of the materials of the buffer layers are not limited to the examples described above. In the second embodiment described above as well, a similar buffer layer may be provided between the silicon oxide layer 22 and the amorphous silicon layer 24.

Instead of the silicon oxide layer (the SiO₂ layer) 22 and the amorphous silicon layer (the a-Si layer) 24 in the embodiments described above, a stacked film including another layer with these layers may be provided. The other layer used in the stacked film may include a hafnium oxide layer (a HfO₂ layer), an aluminum oxide layer (an Al₂O₃ layer), an amorphous silicon layer (an a-Si layer), a polysilicon layer (a polySi layer), etc. The combination of the stacked film may be (HfO₂ layer/SiO₂ layer), (Al₂O₃ layer/SiO₂ layer), (a-Si layer/polySi layer), (a-Si layer/SiO₂ layer), (polySi layer/SiO₂ layer), etc.

According to the embodiments described above, a memory device having high reliability can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A memory device, comprising:
a first interconnect extending in a first direction;
a second interconnect extending in a second direction crossing the first direction; and
a pillar connected between the first interconnect and the second interconnect,
the pillar including:
a first high-resistance layer connected to the first interconnect, a resistivity of the first high-resistance layer being higher than a resistivity of the first interconnect and a resistivity of the second interconnect;
a second high-resistance layer connected to the second interconnect, a resistivity of the second high-resistance layer being higher than the resistivity of the first high-resistance layer, a thickness of the second high-resistance layer being not more than a thickness of the first high-resistance layer; and
a metal layer disposed between the first high-resistance layer and the second high-resistance layer, the metal layer including a metal.

2. The device according to claim 1, wherein the pillar further includes:
a first barrier metal layer disposed between the first interconnect and the first high-resistance layer to contact the first interconnect and the first high-resistance layer, a resistivity of the first barrier metal layer being lower than the resistivity of the first high-resistance layer, the first barrier metal layer being thinner than the first high-resistance layer; and
a second barrier metal layer disposed between the second interconnect and the second high-resistance layer to contact the second interconnect and the second high-resistance layer, a resistivity of the second barrier metal layer being lower than the resistivity of the second high-resistance layer, the second barrier metal layer being thinner than the second high-resistance layer.

3. The device according to claim 1, wherein the pillar extends in a direction orthogonal to both the first direction and the second direction.

4. The device according to claim 1, wherein the metal is one or more metals selected from the group consisting of silver, gold, nickel, and cobalt.

5. The device according to claim 1, wherein the first high-resistance layer and the second high-resistance layer are formed of one or more materials selected from the group consisting of amorphous silicon, polysilicon, silicon oxide, silicon nitride, TaSiN, TiSiN, HfSiN, NbSiN, CrSiN, MoSiN, WSiN, CoSiN, and NiSiN.

6. A memory device, comprising:
a first interconnect extending in a first direction;
a second interconnect extending in a second direction crossing the first direction; and
a pillar connected between the first interconnect and the second interconnect,
the pillar including:
a first high-resistance layer connected to the first interconnect, a resistivity of the first high-resistance layer being higher than a resistivity of the first interconnect and a resistivity of the second interconnect; and
a second high-resistance layer connected to the second interconnect, a resistivity of the second high-resistance layer being higher than the resistivity of the first high-resistance layer, a thickness of the second high-resistance layer being not more than a thickness of the first high-resistance layer, the second high-resistance layer including a metal.

7. The device according to claim 6, wherein the second high-resistance layer includes a metal concentration layer contacting an interface between the second high-resistance layer and the first high-resistance layer, and the metal being concentrated in the metal concentration layer.

8. The device according to claim 6, wherein the pillar further includes:
a first barrier metal layer disposed between the first interconnect and the first high-resistance layer to contact the first interconnect and the first high-resistance layer, a resistivity of the first barrier metal layer being lower than the resistivity of the first high-resistance layer, the first barrier metal layer being thinner than the first high-resistance layer; and
a second barrier metal layer disposed between the second interconnect and the second high-resistance layer to contact the second interconnect and the second high-resistance layer, a resistivity of the second barrier metal layer being lower than the resistivity of the second high-resistance layer, the second barrier metal layer being thinner than the second high-resistance layer.

9. The device according to claim 6, wherein the pillar extends in a direction orthogonal to both the first direction and the second direction.

10. The device according to claim 6, wherein the metal is one or more metals selected from the group consisting of silver, gold, nickel, and cobalt.

11. The device according to claim 6, wherein the first high-resistance layer and the second high-resistance layer are formed of one or more materials selected from the group consisting of amorphous silicon, polysilicon, silicon oxide, silicon nitride, TaSiN, TiSiN, HfSiN, NbSiN, CrSiN, MoSiN, WSiN, CoSiN, and NiSiN.

12. A memory device, comprising:
a first interconnect extending in a first direction;
a second interconnect extending in a second direction crossing the first direction; and
a pillar connected between the first interconnect and the second interconnect to extend in a direction crossing both the first direction and the second direction,
the pillar including:
an amorphous silicon layer connected to the first interconnect;
a silicon oxide layer connected to the second interconnect, a thickness of the silicon oxide layer being not more than a thickness of the amorphous silicon layer; and
a silver layer disposed between the amorphous silicon layer and the silicon oxide layer to contact the amorphous silicon layer and the silicon oxide layer.
